(19) United States
(12) Patent Application Publication
(10) Pub. No.: US 2018/0046045 A1
(43) Pub. Date: Feb. 15, 2018

(54) ARRAY SUBSTRATE, MANUFACTURING METHOD THEREOF, AND DISPLAY PANEL

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventors: Cheng CHEN, Beijing (CN); Jilong LI, Beijing (CN); Dezhi XU, Beijing (CN); Yanming LV, Beijing (CN)

(21) Appl. No.: 15/501,424

(22) PCT Filed: May 5, 2016
(86) PCT No.: PCT/CN2016/081146

§ 371 Date: Feb. 2, 2017

(30) Foreign Application Priority Data
Feb. 2, 2016 (CN) 201610072900.6

(51) Int. Cl. G02F 1/1362; H01L 21/768; G02F 1/1343; H01L 21/28; H01L 29/786; H01L 27/12

(52) U.S. Cl. CPC G02F 1/136227; H01L 29/78633; H01L 27/1244; G02F 1/136259; G02F 1/134309; H01L 21/28008; H01L 27/1248; G02F 1/136286; H01L 21/768

(57) ABSTRACT

The embodiments of the invention disclose an array substrate, a manufacturing method thereof, and a display panel. The array substrate comprises a base substrate, and a first conductive layer, an insulating layer and a second conductive layer arranged on the base substrate sequentially, the insulating layer comprising a via hole region, a semi-retaining region outside the via hole region and a full-retaining region encircling the semi-retaining region and the via hole region. Since the via hole region is surrounded by the semi-retaining region, the thickness of the insulating layer around the via hole is reduced, and thus the influence of the material of the insulating layer left on a rim of the via hole can be reduced. Moreover, since the height difference of the insulating layer is divided into two segments, the influence by height difference in the overall thickness of the insulating layer can be diminished.

### RELATED APPLICATIONS

The present application is the U.S. national phase entry of PCT/CN2016/081146, with an international filling date of May 5, 2016, which claims the benefit of Chinese Patent Application No. 201610072900.6, filed on Feb. 2, 2016, the entire disclosure of which is incorporated herein by reference.

### FIELD OF THE INVENTION

The present disclosure relates to the field of display technologies, and in particular to an array substrate, a manufacturing method thereof, and a display panel.

### BACKGROUND

In a production process of a thin film transistor liquid crystal display (TFT-LCD), organic insulating films are widely applied as they can be easily formed as thick films and can thus reduce signal interference, parasitic capacitance, and substrate loads in an array substrate, thereby lowering the power consumption. An organic insulating film is usually arranged between two conductive films, for example, between a source/drain electrode layer and a pixel electrode layer. In order to electrically connect the pixel electrode with the drain of the thin film transistor, it is necessary to form a via hole in the organic insulating film. Since the organic insulating film is thick, the via hole is rather deep (for example, up to 2 μm), which easily gives rise to problems such as breakage of the pixel electrode lapping a side surface of the via hole and unevenness in rubbing of an alignment layer due to a large height difference of the organic insulating film.

### SUMMARY

Therefore, it is desired that problems caused by a deep via hole in the insulating layer of an existing array substrate should be improved.

An embodiment of the present invention provides an array substrate comprising a base substrate, and a first conductive layer, an insulating layer and a second conductive layer arranged on the base substrate in sequence. The insulating layer comprises a via hole region, a semi-retaining region outside the via hole region and a full-retaining region encircling a region where the semi-retaining region and the via hole region are located. The via hole region comprises a via hole penetrating the insulating layer, and the second conductive layer is electrically connected with the first conductive layer by means of the via hole. A vertical distance between an upper surface of the semi-retaining region of the insulating layer and an upper surface of the first conductive layer is smaller than that between an upper surface of the full-retaining region of the insulating layer and the upper surface of the first conductive layer.

According to another embodiment, the semi-retaining region entirely encircles the via hole region.

According to another embodiment, the insulating layer is made of an organic material.

According to another embodiment, the insulating layer is made of a photosensitive organic material.

According to another embodiment, the semi-retaining region has a width of 1 μm˜6 μm.

According to another embodiment, the vertical distance between the upper surface of the semi-retaining region of the insulating layer and the upper surface of the first conductive layer is smaller than or equal to half the vertical distance between the upper surface of the full-retaining region of the insulating layer and the upper surface of the first conductive layer.

According to another embodiment, the insulating layer has a thickness of 2 μm˜3 μm in the full-retaining region.

According to another embodiment, the first conductive layer is a drain of a thin film transistor in the array substrate, and the second conductive layer is a pixel electrode.

Correspondingly, a further embodiment of the invention provides a display panel comprising the array substrate according to any one of above embodiments.

Further, a manufacturing method for an array substrate is provided by a further embodiment of the invention, the method comprising: forming a first conductive layer on a base substrate; forming an insulating layer on the base substrate on which the first conductive layer has been formed, the insulating layer comprising a via hole region, a semi-retaining region outside the via hole region and a full-retaining region encircling a region where the semi-retaining region and the via hole region are located, wherein the via hole region comprises a via hole penetrating the insulating layer, and a vertical distance between an upper surface of the semi-retaining region of the insulating layer and an upper surface of the first conductive layer is smaller than that between an upper surface of the full-retaining region of the insulating layer and the upper surface of the first conductive layer; forming a second conductive layer on the base substrate on which the insulating layer has been formed, the second conductive layer being electrically connected with the first conductive layer by means of the via hole.

According to another embodiment, forming an insulating layer on the base substrate on which the first conductive layer has been formed comprises: forming the insulating layer through a patterning process on the base substrate on which the first conductive layer has been formed.

According to another embodiment, the insulating layer is made of a photosensitive organic material.

According to another embodiment, forming the insulating layer through a patterning process on the base substrate on which the first conductive layer has been formed comprises: forming an insulating film on the base substrate on which the first conductive layer has been formed; patterning the insulating film by using a first mask plate, to form the full-retaining region of the insulating layer in a region of the insulating film corresponding to a first region of the first mask plate, the semi-retaining region of the insulating layer in a region of the insulating film corresponding to a second region of the first mask plate, and the via hole region of the insulating layer in a region of the insulating film corresponding to a third region of the first mask plate.

According to another embodiment, the first mask plate is selected from a group consisting of a half-tone mask plate and a grey tone mask plate.

According to another embodiment, the photosensitive organic material is a positively photosensitive material, and the first region of the first mask plate is a light shielding region, the second region of the first mask plate is a partially light-transmissive region, and the third region of the first mask plate is a completely light-transmissive region.

According to another embodiment, the photosensitive organic material is a negatively photosensitive material, and the first region of the first mask plate is a completely light-transmissive region, the second region of the first mask plate is a partially light-transmissive region, and the third region of the first mask plate is a light shielding region.

In the above array substrate provided in the embodiments of the present invention, the semi-retaining region outside the via hole region can reduce the thickness of the insulating layer around the via hole, hence, not only can the probability of breakage of the second conductive layer on a rim of the via hole be reduced, but also the material of the insulating layer can be prevented from being left on the rim of the via hole. Besides, since the vertical distance between the upper surface of the semi-retaining region and the upper surface of the first conductive layer is smaller than that between the upper surface of the full-retaining region and the upper surface of the first conductive layer, the height difference of the insulating layer is divided into two segments, which can diminish the influence by height difference in the overall thickness of the insulating layer. Moreover, the semi-retaining region is only arranged outside the via hole region of the insulating layer and the other regions remain full-retaining regions, so the parasitic capacitance between the first conductive layer and the second conductive layer of the other regions will not be increased.

### BRIEF DESCRIPTION OF DRAWINGS

FIG. 1a is a schematic view of a conventional structure in which an organic insulating film is applied;

FIG. 1b is a schematic section view of FIG. 1a taken along the line A-A′;

FIG. 1c is a schematic section view of FIG. 1a taken along the line B-B′;

FIGS. 2a and 2b are schematic top views of an array substrate provided in different embodiments of the invention;

FIG. 3a is a schematic section view of the array substrate shown in FIG. 2a taken along the line A-A′;

FIG. 3b is a schematic section view of the array substrate shown in FIG. 2b taken along the line A-A′;

FIG. 4a is a schematic view of a structure of an array substrate provided in an embodiment of the present invention;

FIG. 4b is a schematic section view of the array substrate shown in FIG. 4a taken along the line A-A′;

FIG. 4c is a schematic section view of the array substrate shown in FIG. 4a taken along the line B-B′;

FIG. 5 is a schematic section view of an array substrate provided in the embodiments of the present invention;

FIG. 6 is a flow chart of a manufacturing method for an array substrate provided in an embodiment of the present invention.

### DETAILED DESCRIPTION OF EMBODIMENTS

In order to render the objective, the technical solutions and the advantages of the present disclosure clearer, specific implementations of the array substrate, the manufacturing method thereof and the display panel provided by the embodiments of the invention will be explained in detail as follows with reference to the drawings.

Thickness and shape of each layer in the drawings are not intended to reflect the true proportion of the array substrate, but only for the purpose of illustrating embodiments of the disclosure.

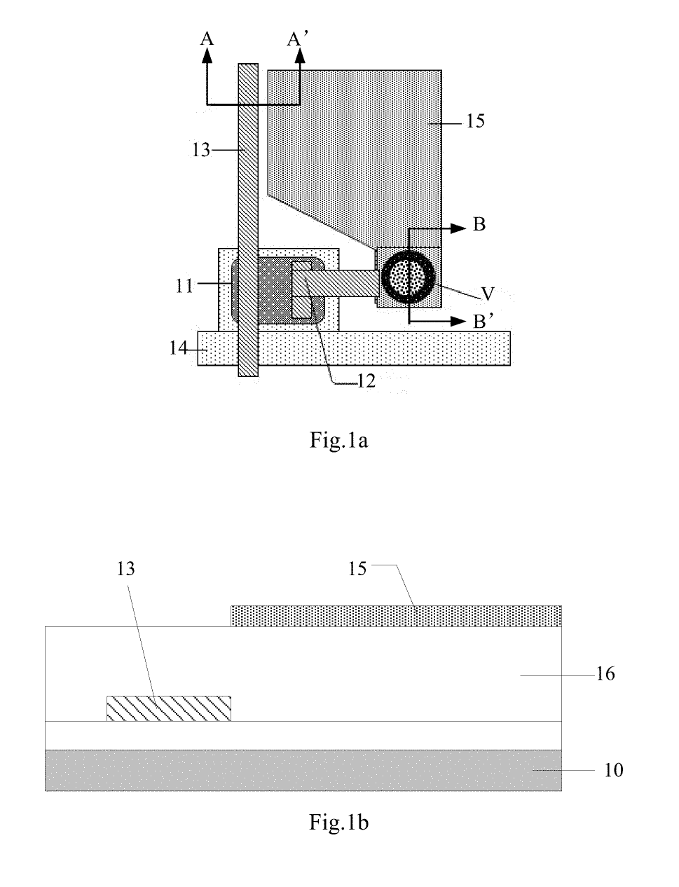

FIG. 1a is a schematic view of a conventional structure where an organic insulating film is applied. FIG. 1b is a schematic section view of FIG. 1a taken along the line A-A′ in FIG. 1a. FIG. 1c is a schematic section view of FIG. 1a taken along the line B-B′ in FIG. 1a. As shown in FIGS. 1a-1c, on a substrate 10, a data line 13, a gate line 14, a pixel electrode 15 and a thin film transistor comprising an active layer 11, a gate (not shown), a source (no shown) and a drain 12 are arranged. An organic insulating film 16 is arranged between the pixel electrode 15 and the drain 12. The pixel electrode 15 is electrically connected with the drain 12 by means of a via hole V penetrating the organic insulating film 16. The data line 13, the source and the drain 12 are arranged in a same layer. As shown in FIG. 1b, the organic insulating film 16 is thick, so the parasitic capacitance between the data line 13 and the pixel electrode 15 is relatively small, which results in a good image quality. However, as shown in FIG. 1c, since the organic insulating film 16 is thick, the via hole V is rather deep (for example, up to 2 μm), which easily gives rise to problems such as breakage of the pixel electrode 15 lapping a side surface of the via hole V and unevenness in rubbing of a subsequent alignment layer due to a large height difference of the organic insulating film 16.

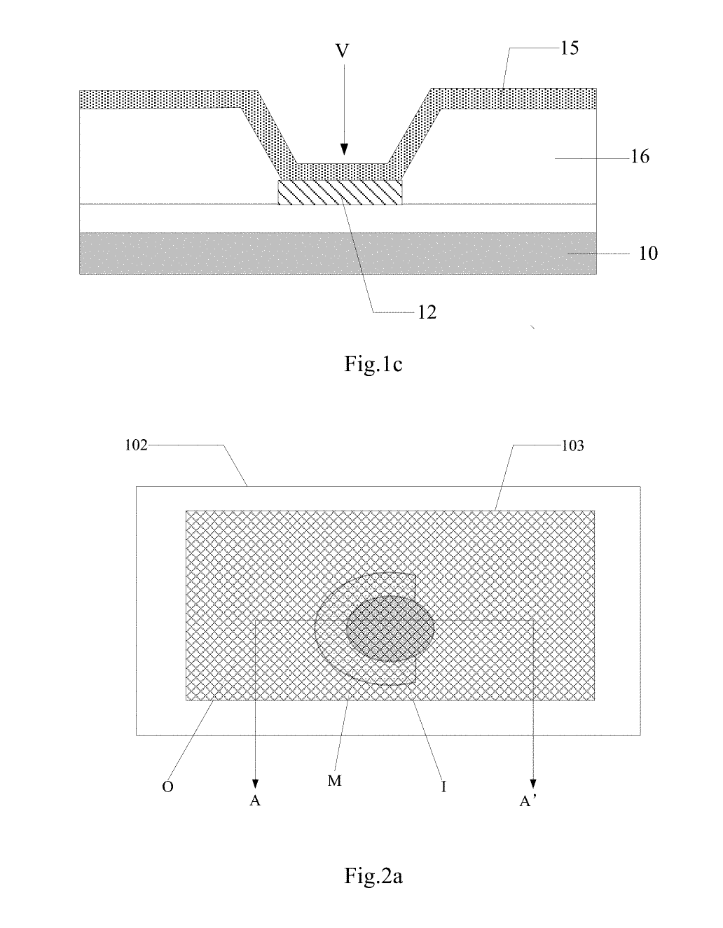

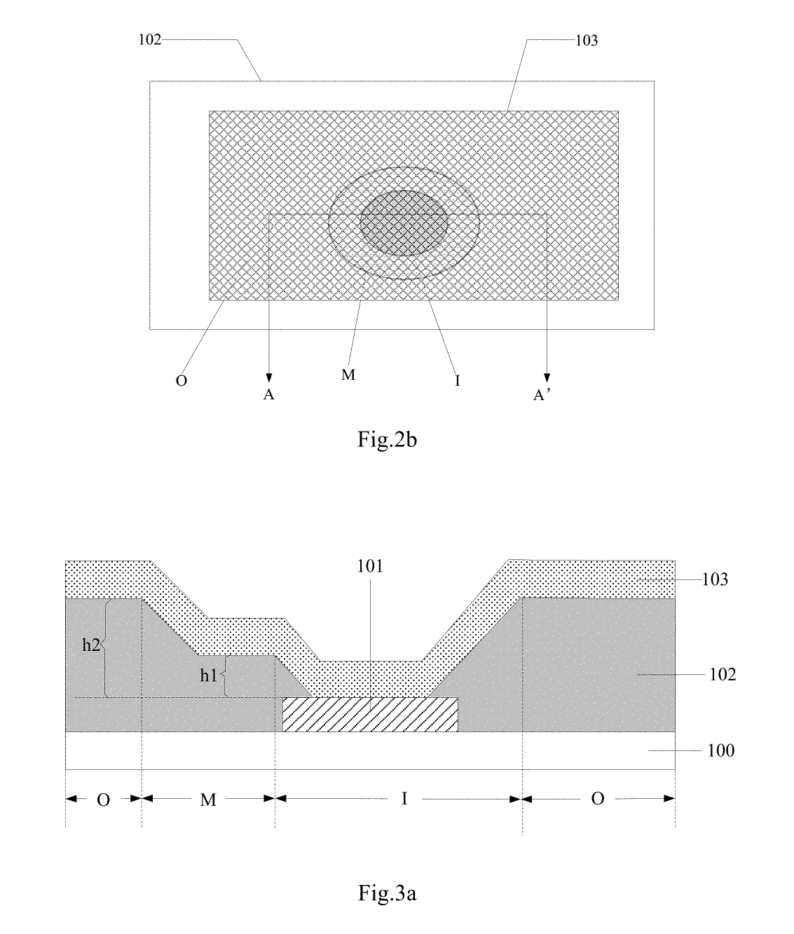

The array substrate provided in the embodiments of the present invention is shown in FIGS. 2a, 2b, 3a and 3b. The array substrate comprises a base substrate 100, and a first conductive layer 101, an insulating layer 102 and a second conductive layer 103 formed on the base substrate 100 in sequence. The insulating layer 102 comprises a via hole region I, a semi-retaining region M outside the via hole region I and a full-retaining region O encircling a region where the semi-retaining region M and the via hole region I are located. The via hole region I comprises a via hole penetrating the insulating layer 102, and the second conductive layer 103 is electrically connected with the first conductive layer 101 by means of the via hole.

As shown in FIGS. 3a and 3b, a vertical distance h1 between an upper surface of the semi-retaining region M of the insulating layer 102 and an upper surface of the first conductive layer 101 is smaller than a vertical distance h2 between an upper surface of the full-retaining region O of the insulating layer 102 and the upper surface of the first conductive layer 101. That is, the thickness of the insulating layer 102 in the semi-retaining region M is smaller than that in the full-retaining region O.

More specifically, in the embodiments shown in FIGS. 3a and 3b, the semi-retaining region M of the insulating layer 102 comprises a flat region and a ramp region adjoining the flat region. A vertical distance between an upper surface of the flat region and the upper surface of the first conductive layer 101 is smaller than that between the upper surface of the full-retaining region O and the upper surface of the first conductive layer 101, and a vertical distance between any point on an upper surface of the ramp region and the upper surface of the first conductive layer 101 is smaller than that between the upper surface of the full-retaining region O and the upper surface of the first conductive layer 101. Of course, the specific shape of the semi-retaining region M is not limited to that shown in FIGS. 3a and 3b, and other shapes can be possible as long as the semi-retaining region can reduce the thickness of the insulating layer around the via hole.

For the above array substrate provided in the embodiments of the invention, the semi-retaining region outside the via hole region can reduce the thickness of the insulating layer around the via hole, thus not only can the probability of breakage of the second conductive layer on a rim of the via hole be reduced, but also the material of the insulating layer can be prevented from being left on the rim of the via hole. Besides, since the vertical distance between the upper surface of the semi-retaining region and the upper surface of the first conductive layer is smaller than that between the upper surface of the full-retaining region and the upper surface of the first conductive layer, the difference in height of the insulating layer is divided into two segments, which can diminish the influence by the height difference caused by the overall thickness of the insulating layer. Moreover, the semi-retaining region is only arranged outside the via hole region of the insulating layer and the other regions of the insulating layer are full-retaining regions, so the parasitic capacitance between the first conductive layer and the second conductive layer in the other regions will not be increased.

In some embodiments, in order to reduce the probability of breakage of the second conductive layer on the rim of the via hole to the maximal extent, the semi-retaining region M can entirely encircle the via hole region I as shown in FIG. 2b. However, since the semi-retaining region may probably decrease an aperture ratio the array substrate, the semi-retaining region M may partly encircle the via hole region I as shown in FIG. 2ain consideration of the aperture ratio. In specific implementation, the size of the semi-retaining region can be determined based on the aperture ratio desired in the actual situation and the probability of breakage of the second conductive layer on the rim of the via hole.

In some embodiments, the width of the semi-retaining region can be within the range of 1 μm ˜6 μm. This is because, when the width of the semi-retaining region is too large, it may go beyond the shielding range for a black matrix in the array substrate, which will decrease the aperture ratio the array substrate. If the width of the semi-retaining region is too small, it may not be achieved under current manufacture process and the effect of reducing height difference will be affected.

According to a further embodiment, the insulating layer is made of an organic material. This is because it is easy for an insulating layer formed by organic materials to get a thick thickness in terms of process. Obviously, in other embodiments, the insulating layer can be made of an inorganic material, which will not be limited here.

Furthermore, the insulating layer may be made of a photosensitive organic material. In this case, it is unnecessary to coat a photoresist layer separately when patterning the insulating layer. The usage of photoresist layer may be reduced or avoided by taking advantage of the photosensitivity of the insulating layer per se, thus reducing the manufacture cost.

Given a fixed area of the semi-retaining region, the thinner the thickness of the semi-retaining region is, the smaller probability of breakage on the rim of the via hole the second conductive layer has. Therefore, according to a further embodiment, the vertical distance between the upper surface of the semi-retaining region of the insulating layer and the upper surface of the first conductive layer is smaller than or equal to half the vertical distance between the upper surface of the full-retaining region of the insulating layer and the upper surface of the first conductive layer.

According to a further embodiment, the thickness of the insulating layer is generally 2 μm˜3 μm in the full-retaining region, which will not be limited here.

The above embodiments of the invention are suitable for any structure in which two conductive layers are to be electrically connected by means of a via hole in an insulating layer between the two conductive layers, but it has a more prominent effect for a structure with a thicker insulating layer.

In some embodiments, the first conductive layer is a drain of a thin film transistor in the array substrate, and the second conductive layer is a pixel electrode, which will not be limited here.

Generally, in some embodiments, the array substrate may further comprise layers and structures such as a data line, a gate line, a source, a gate, an active layer, a gate insulating layer, a passivation layer and a common electrode, which will not be described here in detail as they are known by those skilled in the art.

In some embodiments, the common electrode can be located either above the pixel electrode, or below the pixel electrode, which will not be limited here.

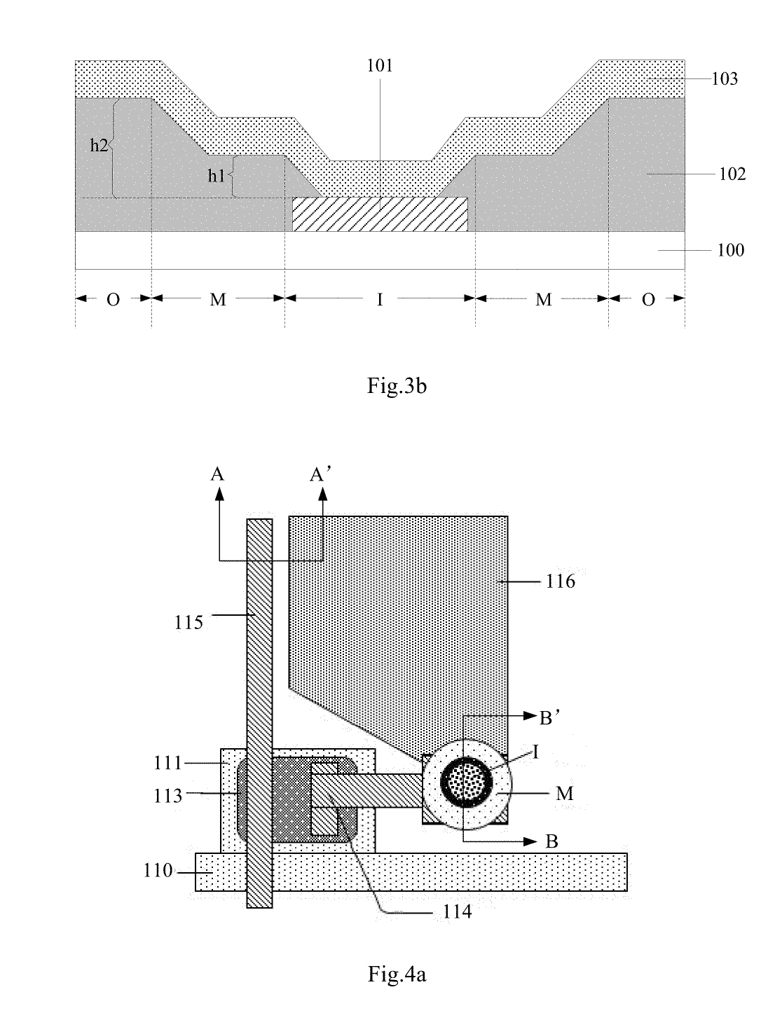

The above array substrate provided in the embodiments of the invention will be illustrated as follows through a specific example. As shown in FIGS. 4a-4c, on the base substrate 100 are arranged sequentially a gate line 110 and a gate 111 arranged in a same layer, a gate insulating layer 112, an active layer 113, and then a source (not shown), a drain 114 and a data line 115 arranged in a same layer, an insulating layer 102 and a pixel electrode 116. The insulating layer 102 comprises a via hole region I, an annular semi-retaining region M encircling the via hole region I and a full-retaining region O encircling the semi-retaining region M. The via hole region I comprises a via hole penetrating the insulating layer 102. A vertical distance between an upper surface of the semi-retaining region M of the insulating layer 102 and an upper surface of the first conductive layer 101 is smaller than that between an upper surface of the full-retaining region O of the insulating layer 102 and the upper surface of the first conductive layer 101. That is, the thickness of the insulating layer 102 in the semi-retaining region M is smaller than that in the full-retaining region O. The pixel electrode 116 is electrically connected with the drain 114 by means of a via hole.

FIG. 4b is a schematic section view of FIG. 4ataken along the line A-A′ in FIG. 4a. As shown in FIG. 4b, the insulating layer 102 is relatively thick, so the parasitic capacitance between the conductive layers on respective sides of the insulating layer 102 (for example, between the data line 115 and the pixel electrode 116) is small, which results in a good image quality. FIG. 4c is a schematic section view of FIG. 4a taken along the line B-B′ in FIG. 4a. As shown in FIG. 4c, although the insulating layer 102 is relatively thick, the via hole region I is surrounded by the semi-retaining region M, which reduces the thickness of the insulating layer 102 around the via hole, so not only can the probability of breakage of the pixel electrode 116 on a rim of the via hole be reduced, but also the material of the insulating layer 102 can be prevented from being left on the rim of the via hole. Besides, since the semi-retaining region M is arranged between the via hole region I and the full-retaining region O, and the thickness of the semi-retaining region M is smaller than that of the full-retaining region O, the difference in height of the insulating layer 102 is indeed divided into two segments, which can diminish the influence by height difference caused by the overall thickness of the insulating layer 102.

In the above array substrate, a semi-retaining region is arranged outside the via hole region of the insulating layer. Although the semi-retaining region can reduce the probability of breakage of the pixel electrode, if the semi-retaining region is located in a liquid crystal pixel region, reversal of liquid crystal molecules may be affected during displaying. Therefore, in order to avoid affecting the reversal of the liquid crystal molecules, the semi-retaining region M can be arranged to partly encircle the via hole region (e.g., to half-encircle the via hole region), and the semi-retaining region is at a side of the via hole region far away from the pixel region.

Further, there is generally a processing range of 3 μm between the black matrix and the rim of the via hole region. That is, the black matrix may go beyond the rim of the via hole region by 3 μm. Thereby, in some embodiments, in order to ensure that the semi-retaining region does not exceed coverage of the black matrix, the width of the semi-retaining region is no greater than 3 μm.

Although the above array substrate is illustrated by taking an example in which the pixel electrode is electrically connected with the drain through the is insulating layer, embodiments of the invention are not limited thereto. An array substrate in which a common electrode is arranged between the pixel electrode and the insulating layer may also be possible.

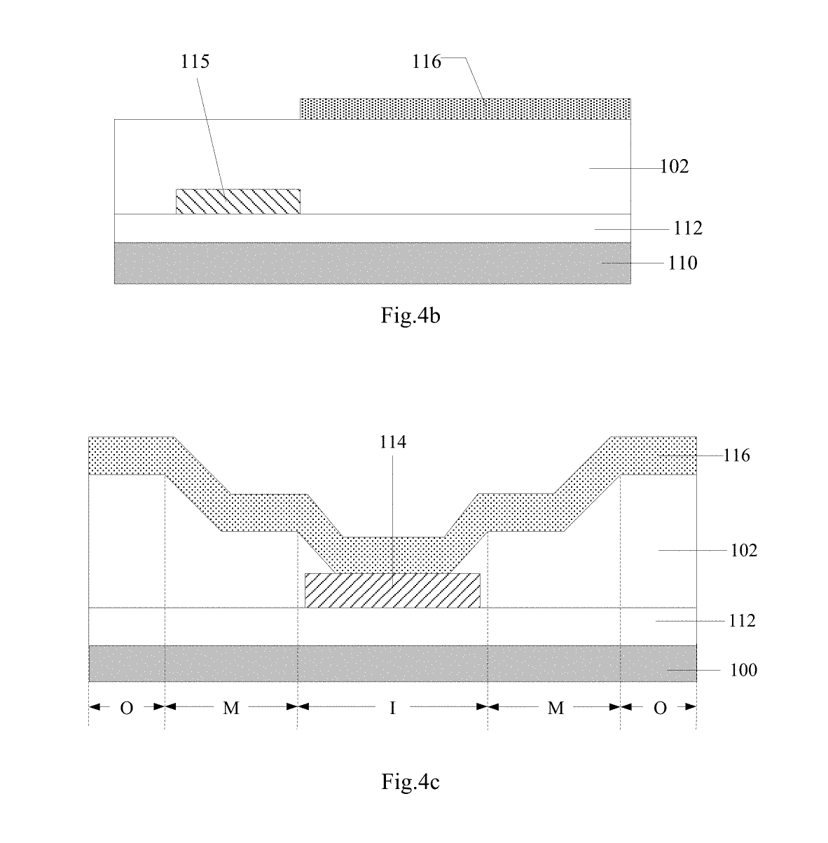

Specifically, as shown in FIG. 5, a common electrode 117 is arranged between the insulating layer 102 and the pixel electrode 116. A passivation layer 118 is arranged between the common electrode 117 and the pixel electrode 116. Both the common electrode 117 and the passivation layer 118 have a via hole arranged in a region corresponding to the via hole region I of the insulating layer 102. Electrical connection is achieved between the pixel electrode 116 and the drain 114 by means of a via hole penetrating the passivation layer 118, the common electrode 117 and the insulating layer 102.

Furthermore, in the embodiment, in order to avoid short circuit between the common electrode 117 and the pixel electrode 116, a distance of 3 μm is generally needed from the common electrode 117 to an outer side of the via hole region I of the insulating layer 102. Further, there may be a processing range of 3 μm between the black matrix and an edge of the common electrode 117. That is, the black matrix may at least have a width of 3 μm for covering the common electrode 117. Thereby, in this case, in order to ensure that the semi-retaining region does not exceed the coverage of the black matrix, the width of the semi-retaining region should be no greater than 6 μm.

Based on the same inventive concept, the embodiments of the invention further provide a display panel, comprising any of the above array substrates provided in the embodiments of the invention. Since the principle adopted in the display panel for solving problems are similar to those adopted in the array substrate mentioned above, for the implementation of the display panel, the embodiments of the array substrate mentioned above can be referred to, which will not be repeated for simplicity.

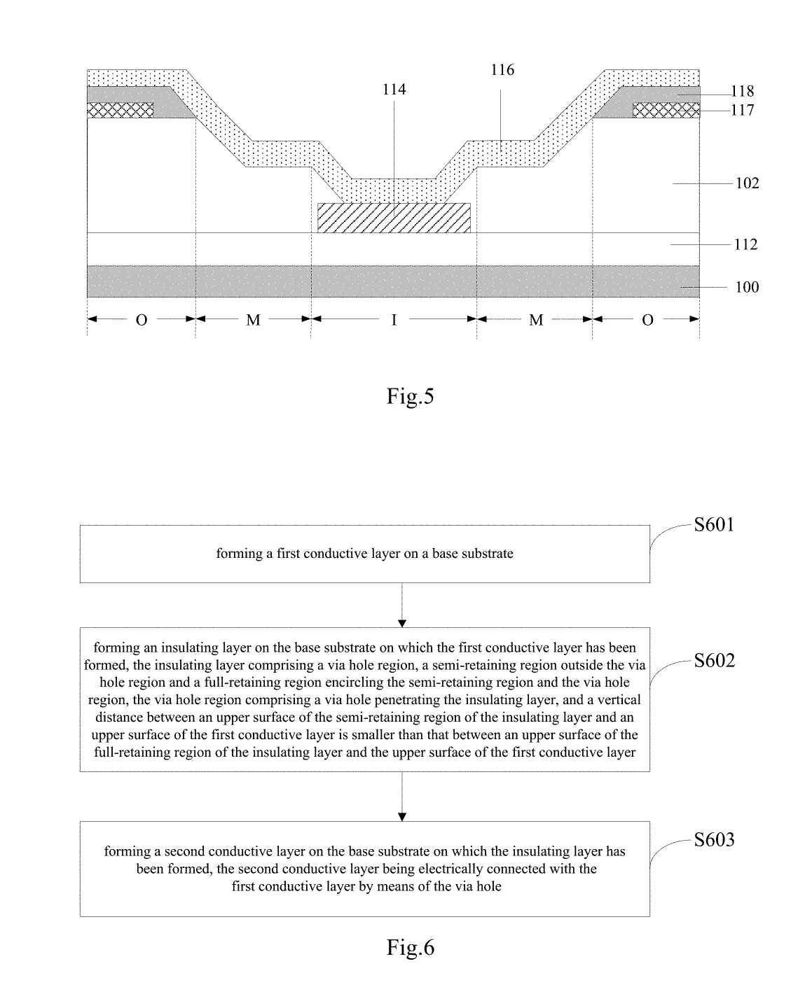

Based on the same inventive concept, the embodiments of the invention further provide a manufacturing method for an array substrate. As shown in FIG. 6, the method can comprise steps as follows:

S601, forming a first conductive layer on a base substrate;

S602, forming an insulating layer on the base substrate on which the first conductive layer has been formed, the insulating layer comprising a via hole region, a semi-retaining region outside the via hole region and a full-retaining region encircling a region where the semi-retaining region and the via hole region are located. The via hole region comprises a via hole penetrating the insulating layer, and a vertical distance between an upper surface of the semi-retaining region of the insulating layer and an upper surface of the first conductive layer is smaller than that between an upper surface of the full-retaining region of the insulating layer and the upper surface of the first conductive layer;

S603, forming a second conductive layer on the base substrate on which the insulating layer has been formed, the second conductive layer being electrically connected with the first conductive layer by means of the via hole.

The insulating layer has a reduced thickness in the semi-retaining region around the via hole outside the via hole region, therefore, not only can the probability of breakage of the second conductive layer on a rim of the via hole be reduced, but also the material of the insulating layer can be prevented from being left on the rim of the via hole. Besides, since the vertical distance between the upper surface of the semi-retaining region and the upper surface of the first conductive layer is smaller than that between the upper surface of the full-retaining region and the upper surface of the first conductive layer, the height difference in the insulating layer is divided into two segments, which can diminish the influence by height difference in the overall thickness of the insulating layer. Moreover, the semi-retaining region is only arranged outside the via hole region of the insulating layer and the other regions are full-retaining regions, so the parasitic capacitance between the first conductive layer and the second conductive layer in the other regions will not be increased.

In some embodiments, forming an insulating layer on the base substrate on which the first conductive layer has been formed may comprise: forming an insulating layer through a patterning process on the base substrate on which the first conductive layer has been formed.

It should be noted that, in the manufacturing method for an array is substrate provided in the embodiments of the invention, the patterning process may comprise only a photolithography process, or comprise a photolithography process and an etching step, and may further comprise other processes for forming a predetermined pattern such as printing or inkjet printing. The photolithography process refers to a process that comprises processes such as film-forming, exposing and developing for forming a pattern by using a photoresist, a mask plate, an exposer and so on. In specific implementation, a corresponding patterning process can be selected based on the structure to be formed.

In some embodiments, forming an insulating layer through a patterning process on the base substrate on which the first conductive layer has been formed can comprise the following steps:

forming an insulating film on the base substrate on which the first conductive layer has been formed; forming a photoresist layer on the insulating film; exposing and developing the photoresist layer by means of a first mask plate so as to define a pattern of an insulating layer in the photoresist layer, and etching the insulating film by using the photoresist layer having the pattern of the insulating layer as a mask, to form a full-retaining region of the insulating layer in a region of the insulating film corresponding to a first region of the first mask plate, a semi-retaining region of the insulating layer in a region of the insulating film corresponding to a second region of the first mask plate, and a via hole region of the insulating layer in a region of the insulating film corresponding to a third region of the first mask plate.

The first mask can be for example a half-tone mask or a grey tone mask.

In case the material of the photoresist layer is a positive photoresist, the first region of the first mask plate is a light shielding region, the second region is a partially light-transmissive region, and the third region is a completely light-transmissive region. When the material of the photoresist layer is a negative photoresist, the first region of the first mask plate is a completely light-transmissive region, the second region is a partially light-transmissive region, and the third region is a light shielding region.

By doing this, the insulating layer can be formed through one patterning process, which can reduce the number of the mask plate to be used, thereby cutting down the cost. Obviously, in specific implementation, the insulating layer can also be formed through two patterning processes, which will not be limited here.

In some embodiments, when the insulating layer is formed through two patterning processes, forming an insulating layer on the base substrate on which the first conductive layer has been formed may comprise the following steps:

forming an insulating film on the base substrate on which the first conductive layer has been formed;

patterning the insulating film for the first time by using a second mask plate to form a via hole region of the insulating layer and a first retaining region of the insulating layer;

patterning the insulating film for the second time by using a third mask plate to form a semi-retaining region and a full-retaining region of the insulating layer in the first retaining region of the insulating layer.

In some embodiments, a photoresist is typically required for the patterning no matter whether the mask plates are used once or twice. However, when the insulating film is made of a photosensitive organic material, the insulating film can be used as a photoresist layer by taking advantage of the photosensitivity of the insulating film per se, which not only avoids the use of a photoresist during the patterning for the insulating film, but also simplifies the process.

Therefore, according to a further embodiment, the insulating layer is made of a photosensitive organic material. Forming an insulating layer through a patterning process on the base substrate on which the first conductive layer has been formed can comprise the following steps:

forming an insulating film on the base substrate on which the first conductive layer has been formed;

patterning the insulating film by using a first mask plate, to form a full-retaining region of the insulating layer in a region of the insulating film corresponding to a first region of the first mask plate, a semi-retaining region of the insulating layer in a region of the insulating film corresponding to a second region of the first mask plate; and a via hole region of the insulating layer in a region of the insulating film corresponding to a third region of the first mask plate.

The first mask can be for example a half-tone mask or a grey tone mask. Patterning the insulating film by using a first mask plate can comprise, for example, patterning the insulating film through exposing and developing by means of a first mask plate.

When the photosensitive organic material is a positively photosensitive material, the first region of the first mask plate is a light shielding region, the second region is a partially light-transmissive region, and the third region is a completely light-transmissive region.

When the photosensitive organic material is a negatively photosensitive material, the first region of the first mask plate is a completely light-transmissive region, the second region is a partially light-transmissive region, and the third region is a light shielding region.

Generally, in specific implementation, the manufacturing method for an array substrate may further comprise steps of forming a data line, a gate line, a source, a gate, an active layer, a gate insulating layer, a passivation layer, a common electrode and so on, which will not be described here in detail as they are known by those skilled in the art.

A manufacture process of the array substrate provided in the embodiments of the present invention will be illustrated in detail as follows by taking the array substrate shown in FIG. 4a as an example. The manufacture process can specifically comprise steps as follows:

(1) forming a gate and a gate line on a base substrate through a patterning process;

(2) depositing a gate insulating layer, which can be made of SiN_{X} for example;

(3) forming an active layer through a patterning process;

(4) forming a data line, a source and a drain through a patterning process;

(5) forming an insulating layer through a patterning process, the is insulating layer being made of a photosensitive organic material. The insulating layer comprises a via hole region, an annular semi-retaining region encircling the via hole region and a full-retaining region encircling the semi-retaining region, the via hole region comprises a via hole penetrating the insulating layer, and a vertical distance between an upper surface of the semi-retaining region of the insulating layer and an upper surface of the first conductive layer is smaller than that between an upper surface of the full-retaining region of the insulating layer and the upper surface of the first conductive layer;

(6) forming a pixel electrode through a patterning process, the pixel electrode being electrically connected with the drain by means of a via hole in the insulating layer.

In specific implementation, forming an insulating layer through a patterning process may comprise the following steps: firstly forming an insulating film, and then patterning the insulating film by using a first mask plate which is for example a half-tone mask plate or a grey tone mask plate, to form a full-retaining region of the insulating layer in a region of the insulating film corresponding to a first region of the first mask plate, a semi-retaining region of the insulating layer in a region of the insulating film corresponding to a second region of the first mask plate; and a via hole region of the insulating layer in a region of the insulating film corresponding to a third region of the first mask plate.

When the photosensitive organic material is a positively photosensitive material, the first region of the first mask plate is a light shielding region, the second region is a partially light-transmissive region, and the third region is a completely light-transmissive region. When the photosensitive organic material is a negatively photosensitive material, the first region of the first mask plate is a completely light-transmissive region, the second region is a partially light-transmissive region, and the third region is a light shielding region.

Furthermore, the thickness of the insulating layer in the full-retaining region may be about 2 μm, and the thickness of the insulating layer in the semi-retaining region may be smaller than or equal to 1 μm.

Specifically, both the width and the thickness of the insulating layer in the semi-retaining region can be controlled by a transmissivity and a total exposure amount of the second region of the first mask plate.

Obviously, in specific implementation, after step (6), the method can further comprise steps such as forming a passivation layer above the pixel electrode and forming a common electrode on the passivation layer, which will not be limited here.

With the above array substrate, the manufacturing method thereof and the display panel provided in the embodiments of the invention, the semi-retaining region outside the via hole region has a reduced thickness of the insulating layer around the via hole, thus not only can the probability of breakage of the second conductive layer on a rim of the via hole be reduced, but also the material of the insulating layer can be prevented from being left on the rim of the via hole. Besides, since the vertical distance between the upper surface of the semi-retaining region and the upper surface of the first conductive layer is smaller than that between the upper surface of the full-retaining region and the upper surface of the first conductive layer, the height difference in the insulating layer is divided into two segments, which can diminish the influence by height difference of the overall thickness of the insulating layer. Moreover, the semi-retaining region is only arranged outside the via hole region of the insulating layer and the other regions are full-retaining regions, so the parasitic capacitance between the first conductive layer and the second conductive layer in the other regions will not be increased.

Obviously, those skilled in the art can make various modifications and variations to the present disclosure without deviating from spirits and scopes of the present invention. Thus if these modifications and variations to the present disclosure fall within the scopes of the claims of the present invention and the equivalent techniques thereof, the present invention is intended to include them too.

1. An array substrate, comprising:
a base substrate, and
a first conductive layer, an insulating layer and a second conductive layer arranged on the base substrate in sequence,
wherein the insulating layer comprises a via hole region, a semi-retaining region outside the via hole region and a full-retaining region encircling a region where the semi-retaining region and the via hole region are located,
wherein the via hole region comprises a via hole penetrating the insulating layer, and the second conductive layer is electrically connected with the first conductive layer by means of the via hole,
wherein a vertical distance between an upper surface of the semi-retaining region of the insulating layer and an upper surface of the first conductive layer is smaller than that between an upper surface of the full-retaining region of the insulating layer and the upper surface of the first conductive layer.

2. The array substrate according to claim 1, wherein the semi-retaining region entirely encircles the via hole region.

3. The array substrate according to claim 1, wherein the insulating layer is made of an organic material.

4. The array substrate according to claim 3, wherein the insulating layer is made of a photosensitive organic material.

5. The array substrate according to claim 1, wherein the semi-retaining region has a width of 1 μm˜6 μm.

6. The array substrate according to claim 1, wherein the vertical distance between the upper surface of the semi-retaining region of the insulating layer and the upper surface of the first conductive layer is smaller than or equal to half the vertical distance between the upper surface of the full-retaining region of the insulating layer and the upper surface of the first conductive layer.

7. The array substrate according to claim 1, wherein the insulating layer has a thickness of 2 μm˜3 μm in the full-retaining region.

8. The array substrate according to claim 1, wherein the first conductive layer is a drain of a thin film transistor in the array substrate, and the second conductive layer is a pixel electrode.

9. A display panel comprising an array substrate, the array substrate comprising:
a base substrate, and
a first conductive layer, an insulating layer and a second conductive layer arranged on the base substrate in sequence,
wherein the insulating layer comprises a via hole region, a semi-retaining region outside the via hole region and a full-retaining region encircling a region where the semi-retaining region and the via hole region are located,
wherein the via hole region comprises a via hole penetrating the insulating layer, and the second conductive layer is electrically connected with the first conductive layer by means of the via hole,
wherein a vertical distance between an upper surface of the semi-retaining region of the insulating layer and an upper surface of the first conductive layer is smaller than that between an upper surface of the full-retaining region of the insulating layer and the upper surface of the first conductive layer.

10. A manufacturing method for an array substrate, comprising:
forming a first conductive layer on a base substrate;
forming an insulating layer on the base substrate on which the first conductive layer has been formed, the insulating layer comprising a via hole region, a semi- retaining region outside the via hole region and a full-retaining region encircling a region where the semi-retaining region and the via hole region are located, wherein the via hole region comprises a via hole penetrating the insulating layer, and a vertical distance between an upper surface of the semi-retaining region of the insulating layer and an upper surface of the first conductive layer is smaller than that between an upper surface of the full-retaining region of the insulating layer and the upper surface of the first conductive layer;
forming a second conductive layer on the base substrate on which the insulating layer has been formed, the second conductive layer being electrically connected with the first conductive layer by means of the via hole.

11. The manufacturing method according to claim 10, wherein forming an insulating layer on the base substrate on which the first conductive layer has been formed comprises:
forming the insulating layer through a patterning process on the base substrate on which the first conductive layer has been formed.

12. The manufacturing method according to claim 11, wherein the insulating layer is made of a photosensitive organic material.

13. The manufacturing method according to claim 12, wherein forming the insulating layer through a patterning process on the base substrate on which the first conductive layer has been formed comprises:
forming an insulating film on the base substrate on which the first conductive layer has been formed;
patterning the insulating film by using a first mask plate, to form the full-retaining region of the insulating layer in a region of the insulating film corresponding to a first region of the first mask plate, the semi-retaining region of the insulating layer in a region of the insulating film corresponding to a second region of the first mask plate, and the via hole region of the insulating layer in a region of the insulating film corresponding to a third region of the first mask plate.

14. The manufacturing method according to claim 13, wherein the first mask plate is selected from a group consisting of a half-tone mask plate and a grey tone mask plate.

15. The manufacturing method according to claim 13, wherein the photosensitive organic material is a positively photosensitive material, and the first region of the first mask plate is a light shielding region, the second region of the first mask plate is a partially light-transmissive region, and the third region of the first mask plate is a completely light-transmissive region.

16. The manufacturing method according to claim 13, wherein the photosensitive organic material is a negatively photosensitive material, and the first region of the first mask plate is a completely light-transmissive region, the second region of the first mask plate is a partially light-transmissive region, and the third region of the first mask plate is a light shielding region.

17. The display panel according to claim 9, wherein the semi-retaining region entirely encircles the via hole region.

18. The display panel according to claim 9, wherein the insulating layer is made of a photosensitive organic material.

19. The display panel according to claim 9, wherein the vertical distance between the upper surface of the semi-retaining region of the insulating layer and the upper surface of the first conductive layer is smaller than or equal to half the vertical distance between the upper surface of the full-retaining region of the insulating layer and the upper surface of the first conductive layer.

20. The display panel according to claim 9, wherein the first conductive layer is a drain of a thin film transistor in the array substrate, and the second conductive layer is a pixel electrode.
